(19) United States
(12) Patent Application Publication
(10) Pub. No.: US 2019/0027954 A1
(43) Pub. Date: Jan. 24, 2019

(54) WIRELESS POWER TRANSMITTER AND RECEIVER

(71) Applicant: LG INNOTEK CO., LTD., Seoul (KR)

(72) Inventors: Sang Hak LEE, Seoul (KR); Sang Won LEE, Seoul (KR); Myeong Jae JEONG, Seoul (KR)

(73) Assignee: LG INNOTEK CO., LTD., Seoul (KR)

(21) Appl. No.: 16/070,188

(22) PCT Filed: Dec. 9, 2016
(86) PCT No.: PCT/KR2016/014448

§ 371 Date: Jul. 13, 2018

(30) Foreign Application Priority Data
Jan. 15, 2016 (KR) 10-2016-0005620

(51) Int. Cl. H02J 7/02; H02J 50/70; H02J 50/80; H05K 9/00; H02J 5/00

(52) U.S. Cl. CPC H02J 7/025; H02J 50/70; H02J 5/005; H05K 9/00; H02J 50/80

(57) ABSTRACT

A wireless power transmitter, which transfers wireless power to a wireless power receiver, according to an embodiment includes: an accommodation part configured to accommodate the wireless power receiver; a transfer coil configured to surround the accommodation part in the form of a solenoid; a shield unit configured to surround the transfer coil in the form of the solenoid; an electromagnet disposed on a lower end of the accommodation part to fix the wireless power receiver; and a control unit configured to determine whether to transfer the wireless power to the wireless power receiver through the transfer coil, wherein the control unit controls the electromagnet so that the wireless power receiver is separated from the accommodation part due to a release of attractive force or repulsive force between the electromagnet and a metal body of the wireless power receiver when the wireless power is not transferred.

### TECHNICAL FIELD

The present invention relates to a wireless power transmitter and a wireless power receiver.

### BACKGROUND ART

Generally, various electronic equipment includes a battery and is driven by using power charged in the battery. Here, in the electronic equipment, the battery may be replaced and rechargeable. For this, the electronic equipment include a contact terminal coming into contact with an external charging device. That is, the electronic equipment is electrically connected to the charging device through the contact terminal. However, since the contact terminal of the electronic equipment is exposed to the outside, the contact terminal may be contaminated by foreign objects or short-circuited by moisture. In this case, contact failure may occur between the contact terminal and the charging device, and thus, the battery may not be charged in the electronic equipment.

To solve the above-described problem, a wireless power transfer (WPT) for wirelessly charging the electronic equipment has been proposed.

A wireless power transfer system is a technology that transfers power without a line through a space and maximizes convenience of power supply to mobile devices and digital household appliances.

The wireless power transfer system has advantages such as saving energy through real-time power usage control, overcoming a space limitation of the power supply, and reducing waste battery discharge through the recharging of the battery.

As a method for implementing the wireless power transfer system, there are typically a magnetic induction method and a magnetic resonance method. The magnetic induction method is a noncontact energy transfer technique in which two coils are close to each other, and current flows to one coil, and thus, electromotive force is generated in the other oil by using a magnetic flux generated thereby as a medium. Here, frequency of several hundred KHz may be used. The magnetic resonance method is a magnetic resonance technique that uses only electric fields or magnetic fields without using electromagnetic waves or current. Thus, a distance over which power is capable of being transferred may be several meters or more, and a band of several MHz may be used.

The wireless power transfer system includes a transfer device wirelessly transferring power and a receiver device receiving power to charge a load such as a battery. Here, a charging method of the receiver device, i.e., one charging method of the magnetic induction method or the magnetic resonance method may be selected, and a power transfer device for wirelessly transferring power to correspond to the charging method of the receiver device is being developed.

### DISCLOSURE OF THE INVENTION

### Technical Problem

A wireless power transfer device and a wireless power receiver device according to an embodiment are provided with a transfer coil having a sufficient thickness, a receiver coil having a sufficient thickness, and a shield part having a sufficient thickness.

A wireless power transfer device and a wireless power receiver device according to an embodiment wirelessly transfer and receive power by using a narrow area.

In a wireless power transfer device and a wireless power receiver device according to an embodiment, when transferring and receiving wireless power, the wireless power transfer device and the wireless power receiver device are coupled to each other.

In a wireless power transfer device and a wireless power receiver device according to an embodiment, when transferring and receiving of wireless power are ended, the wireless power transfer device and the wireless power receiver device are separated from each other.

### Technical Solution

A wireless power transmitter, which transfers wireless power to a wireless power receiver, according to an embodiment includes: an accommodation part configured to accommodate the wireless power receiver; a transfer coil configured to surround the accommodation part in the form of a solenoid; a shield unit configured to surround the transfer coil in the form of the solenoid; an electromagnet disposed on a lower end of the accommodation part to fix the wireless power receiver; and a control unit configured to determine whether to transfer the wireless power to the wireless power receiver through the transfer coil, wherein the control unit controls the electromagnet so that the wireless power receiver is separated from the accommodation part due to a release of attractive force or repulsive force between the electromagnet and a metal body of the wireless power receiver when the wireless power is not transferred.

A wireless power receiver, which receives wireless power to a wireless power transmitter, according to an embodiment includes: a receiver coil configured to surround a core in the form of a solenoid; and a metal body disposed on a lower end of the core, wherein, when the receiver coil does not receive the wireless power, the metal body separates the wireless power receiver from the wireless power transmitter due to a release of attractive force or repulsive force between an electromagnet of the wireless power transmitter and a magnetic body.

A method for operating a wireless power transmitter according to an embodiment includes: being in standby state; transmitting and receiving a ping signal to and from a wireless power receiver; identifying the wireless power receiver; transferring wireless power to the wireless power receiver; and ending the wireless power transfer, wherein the identifying of the wireless power receiver includes recognizing that the wireless power receiver is inserted into an accommodation part of the wireless power transfer unit, and the ending of the wireless power transfer includes controlling the electromagnet so that the wireless power receiver is separated from the accommodation part due to a release of attractive force or repulsive force between an electromagnet and a metal body of the wireless power receiver.

A method for operating a wireless power receiver according to an embodiment includes: transmitting information for identifying the wireless power receiver to a wireless power transmitter; fixing the wireless power receiver to the wireless power transmitter by attractive force between an electromagnet of the wireless power transmitter and a metal body of the wireless power receiver; receiving wireless power from the wireless power transmitter: transmitting information for informing that charging is completed with respect to a battery of the wireless power receiver to the wireless power transmitter; and separating the wireless power transmitter from the wireless power receiver due to release of the attractive force or the repulsive force between the electromagnet of the wireless power transmitter and the metal body of the wireless power receiver.

### Advantageous Effects

The wireless power transfer device and the wireless power receiver device according to the embodiment may be provided with the transfer coil having the sufficient thickness, the receiver coil having the sufficient thickness, and the shield part having the sufficient thickness to improve the wireless power transferring and receiving efficiency.

The wireless power transfer device and the wireless power receiver device according to the embodiment may wirelessly transfer and receive the power by using the narrow area. Thus, the wireless power may be transferred and received even the area that is less than the predetermined area for transferring and receiving the wireless power.

In the wireless power transfer device and the wireless power receiver device according to the embodiment when transferring and receiving wireless power the wireless power transfer device and the wireless power receiver device may be coupled to each other to improve the wireless power transferring and receiving efficiency and also stably transfer and receive the wireless power.

In the wireless power transfer device and the wireless power receiver device according to the embodiment, when the transferring and receiving of the wireless power are ended, the wireless power transfer device and the wireless power receiver device may be separated from each other to improve the wireless power transferring and receiving efficiency and also stably transfer and receive the wireless power.

### BRIEF DESCRIPTION OF THE DRAWINGS

FIG. 1 is a view of a coil and a shield part of each of a wireless power transmitter and a wireless power receiver.

FIG. 2 is an equivalent circuit diagram of the wireless power transmitter and the wireless power receiver, which use a magnetic induction method.

FIG. 3 is a block diagram of the transfer device as one of a sub system constituting the wireless power transfer system according to an embodiment.

FIG. 4 is a block diagram of a transfer device as one of a sub system constituting a wireless power transfer system according to another embodiment.

FIG. 5 is a block diagram of the receiver unit as one of the sub system constituting the wireless power transfer system according to an embodiment.

FIG. 6 is a block diagram of a receiver unit device as one of a sub system constituting a wireless power transfer system according to another embodiment.

FIG. 7 is a flowchart illustrating an operation of the wireless power transfer system, which is an operation flowchart based on an operation state of the wireless power transfer system according to an embodiment.

FIGS. 8A to 8C are cross-sectional views of the wireless power transmitter and the wireless power receiver according to an embodiment.

FIG. 9 is a cross-sectional view of a wireless power transmitter and a wireless power receiver according to another embodiment.

FIG. 10 is a view illustrating structures of a wireless power transmitter and a wireless power receiver according to further another embodiment.

FIG. 11 is a cross-sectional perspective view of a wireless power transmitter and a wireless power receiver according to further another embodiment.

FIG. 12 is a block diagram of the wireless power transmitter according to an embodiment.

FIG. 13 is a block diagram of the wireless power receiver according to an embodiment.

FIG. 14 is a flowchart illustrating an operation of the wireless power transmitter according to an embodiment.

FIG. 15 is a flowchart illustrating an operation of the wireless power receiver according to an embodiment.

### MODE FOR CARRYING OUT THE INVENTION

Hereinafter, a coil device according to an embodiment, a method for manufacturing the coil device, and a wireless power transfer device and a wireless power receiver device including the coil device will be described in detail with reference to the accompanying drawings. The following embodiments are provided as mere examples to sufficiently express the ideas of the present invention to the skilled in the art. The prevent invention may, however, be embodied in different forms and should not be construed as limited to the embodiments set forth herein. In the drawings, the size and thickness of the device may be exaggerated for convenience. Like reference numerals designate like elements throughout the specification.

The embodiments may include a communication system that selectively uses various frequency bands ranging from a lower frequency (50 KHz) to a high frequency (15 MHz) to wirelessly transmit power and is capable of exchanging data and a control signal to control the system.

The embodiments may be applied to various industrial fields such as mobile terminal industries using electronic equipment in which a battery is used or required, smart clock industries, computer and notebook industries, household appliance industries, medical device industries, robot industries, and the like.

The embodiments may consider a system capable of transferring power to one or more plural devices by using one or a plurality of transfer coils.

According to the embodiments, the battery shortage problem in the mobile devices such as smart phones and notebooks may be solved. For example, when a wireless charging pad is placed on a table, and a smart phone or a notebook is used on the table, the battery may be automatically charged and thus be used for a long time. When the wireless charging pad is installed on public places such as cafeterias, airports, taxis, offices, restaurants, and the like, various mobile devices may be charged regardless of charging terminals which are different from each other according to the manufactures of the mobile devices. Also, when the wireless power transfer technology is applied to the household electrical appliances such as cleaners, electric fans, and the like, there is no need to look for power cables, and complex wires may be disappeared in the home. Therefore, wires within buildings may be reduced, and space utilization may be improved. When electric vehicles are charged by using the current household power, a time taken to charge the electric vehicles may increase. However, if high power is transmitted to the electric vehicles through the wireless power transfer technology, the charging time may be reduced. In addition, when the wireless charging facility is installed on the floor of the parking lot, power cables around the electric vehicles may not be prepared.

The terms and abbreviations used in the embodiments are as follows.

Wireless power transfer system: means a system providing wireless power transfer within a magnetic field area.

Wireless power transfer system-charger; power transfer unit (PTU): called a transfer device, a wireless power transmitter, or a transmitter as a device for managing an entire system, which wirelessly transfers power to the wireless power receiver device within magnetic fields.

Wireless power receiver system-device; power receiver unit (PRU): called a receiver device, a wireless power receiver, or a receiver as a device for wirelessly receiving power from the wireless power transfer device within magnetic fields.

Charging area: an area in which wireless power transfer is performed within a magnetic field area and which varies depending on a size, required power, and an operation frequency of an application product.

Scattering parameter: S parameter is a ratio (transmission; S21) of an input port to an output port or a self-reflection value of each of the input/output ports, i.e., an output value (reflection; Sri and Sm) reflected back from its input in terms of a ratio of an input voltage to an output voltage on a frequency distribution.

Quality factor: a value of Q in resonance means quality of frequency selection. The hinger the Q value, the better the resonance characteristics. The Q value is expressed as a ratio of energy stored in a resonator to lost energy.

Typically, there are a magnetic induction method and a magnetic resonance method as a method for wirelessly transferring power.

The magnetic induction method is a noncontact energy transfer technique in which electromotive force is generated in a load inductor Lₗ by using a magnetic flux, which is generated when source inductors Lₛ are close to each other, and current is supplied to one of the source inductors Ls, as a medium. Also, the magnetic resonance method combines two resonators to generate magnetic resonance by a natural frequency between the two resonators and wirelessly transmits energy by using a resonance technique in which the resonators vibrate at the same frequency to form electric fields and magnetic fields in the same wavelength range.

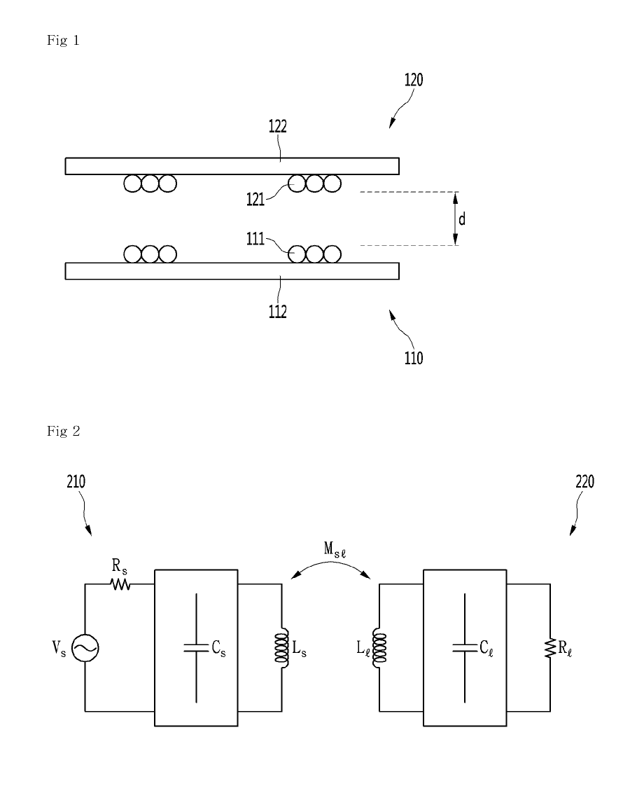

FIG. 1 is a view of a coil and a shield part of each of a wireless power transmitter and a wireless power receiver.

Referring to FIG. 1, a wireless power transfer device 110 may include a flat transfer coil 111 and a flat shield part 112 for shielding magnetic fields of the transfer coil 111. Similarly, a wireless power receiver device 120 may include a flat receiver coil 121 and a flat shield part 122 for shielding magnetic fields of the receiver coil 121.

Users prefer thin wireless power transfer devices or wireless power receiver devices. Thus, in the wireless power transfer device 110 including the flat transfer coil 111 and the flat shield part 112, it may be difficult to mount the transfer coil having a sufficient thickness and the shield part having a sufficient thickness. Similarly, in the wireless power receiver device 120 including the flat receiver coil 121 and the flat shield part 122, it may be difficult to mount the receiver coil having a sufficient thickness and the shield part having a sufficient thickness.

Also, in the wireless power transfer device 110 including the flat transfer coil 111 and the flat shield part 112 and the wireless power receiver device 120 including the flat receiver coil 121 and the flat shield part 122, since the coil is wound in a flat shape, an area occupied by the coil and the shield may increase.

In addition, in the wireless power transfer device and the wireless power receiver device, each of which is provided with the flat coil and the flat shield part, when a distance d between the transfer coil and the receiver coil is 5 mm or more, charging efficiency may be significantly deteriorated.

Thus, a wireless power transfer device and a wireless power receiver device, each of which has a new structure for solving the problems of the wireless power transfer device and the wireless power receiver device, each of which is provided with the flat coil and the flat shield part, may be required.

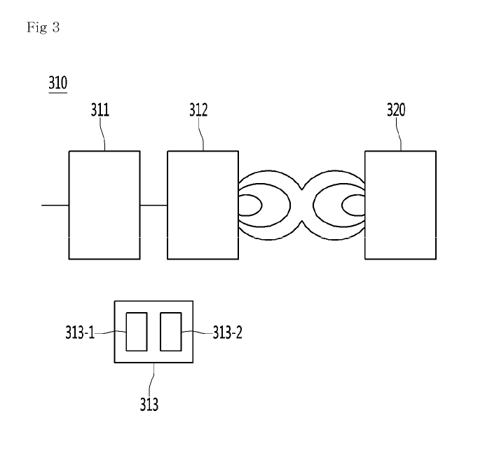

FIG. 2 is an equivalent circuit diagram of the wireless power transmitter and the wireless power receiver, which use a magnetic induction method.

Referring to FIG. 2, a transfer device 210 may include a source voltage Vₛ, a source resistor Rₛ, a source capacitor Cₛ for impedance matching, and a source coil Lₛ for magnetic coupling with a receiver device according to devices for supplying power. The receiver device 220 may include a load resistor Rₗ that is an equivalent load of the receiver unit, a load capacitor Cₗ for impedance matching, and a load coil Lₗ for magnetic coupling with the transfer device. A degree of the magnetic coupling of the source coil Lₛ and the load coil Lₗ may be represented by a mutual inductance Mₛₗ.

In FIG. 2, a ratio S21 of the input voltage to the output voltage is obtained from the magnetic induction equivalent circuit constituted by only the coil without the source capacitor Cₛ and the load capacitor Ce for the impedance matching. When a maximum power transfer condition is found from the ratio S21, the maximum power transfer condition satisfies the following Expression 1.

Ls/Rₛ=Lₗ/Rₗ [Equation 1]

The maximum power transfer is possible when the ratio of the inductance of the transfer coil Lₛ to the source resistor Rₛ and the ratio of the inductance of the load coil Lₗ to the load resistor Rₗ are the same. In a system with only an inductance, since there is no capacitor capable of compensating for reactance, a value of the self-reflection value S₁₁ of each of the input/output ports may not be zero at a point at which the maximum power transfer occurs. Also, power transfer efficiency may significantly vary depending on the value of mutual inductance Mₛₗ. Thus, the source capacitor Cₛ may be added to the transfer device 210 as a compensation capacitor for the impedance matching. In addition, the load capacitor Cₗ may be applied to the receiver device 220. For example, the compensation capacitors Cₛ and Cₗ may be connected to the receiver coil Lₛ and the load coil Lₗ in series or parallel to each other, respectively. Also, an additional capacitor and a passive element such as an inductor may be further added to the transfer device 210 and the receiver device 220 for the impedance matching, respectively.

FIG. 3 is a block diagram of the transfer device as one of a sub system constituting the wireless power transfer system according to an embodiment.

Referring to FIG. 3, a wireless power transmitter 310 according to an embodiment may include a power conversion unit 311, a transfer coil unit 312, and a control and communication unit 313.

The power conversion unit 311 may power-convert an inputted DC or AC signal to output an AC signal. The transfer coil unit 312 may generate magnetic fields on the basis of the AC signal outputted from the power conversion unit 311 to transfer the power to the wireless power receiver device 320 within a charging area. The control and communication unit 313 may control the power conversion of the power conversion unit 311 and the transfer coil unit 312. The control and communication unit 313 may adjust an amplitude and frequency of an output signal of the power conversion unit 311. The control and communication unit 313 may sense at least one of an impedance, a voltage, and current from the power conversion unit 311 and the transfer coil unit 312. The control and communication unit 313 may perform the wireless communication in an in-band method or an out-of-band method. The communication and control unit 313 may include a control part 313-1 and a communication part 313-2. According to another embodiment, the communication and control unit 313 may be divided into a control part 313-1 and a communication part 313-2.

The power conversion unit 311 may be called an inverter. The power conversion unit 311 may include at least one of a power conversion part that converts an AC signal into a DC, a power conversion part that outputs a DC by changing a level of the DC, and a power conversion part that converts DC into AC. Also, the transfer coil unit 312 may include a coil and an impedance matching part that resonant with the coil. Also, the control and communication unit 313 may include a sensing part (not shown) for sensing impedance, voltage, and current information.

FIG. 4 is a block diagram of a transfer device as one of a sub system constituting a wireless power transfer system according to another embodiment.

Referring to FIG. 4, the transfer device 410 may include an inverter 411, a coil selection unit 412, a transfer coil unit 413, a current detection unit 414, and a control and communication unit 415.

The inverter 411 may receive power from the power supply device (not shown). The inverter 411 may convert the DC signal inputted from the power supply device into the AC signal and adjust a frequency of the converted AC signal. For example, the inverter 11 may be a half bridge inverter or a full bridge inverter. Also, various amplifiers that convert DC into AC may be applied to the wireless power transfer system. For example, A-class, B-class, AB-class, C-class, E-class, and F-class amplifiers may be applied. Also, the inverter 411 may include an oscillator for generating a frequency of the output signal and a power amplifier for amplifying the output signal. The inverter 411 may be called a power conversion unit.

The coil selection unit 412 may select at least one coil for wirelessly transferring the power among the plurality of coils provided in the transfer coil unit 413. According to another embodiment, the transfer coil unit 413 may include one coil.

The transfer coil unit 413 may include a plurality coils. The plurality of coils may be spaced apart from each other or overlap each other. When the plurality of coils overlap each other, an overlapping area may be determined in consideration of a deviation in magnetic flux density. Also, when the transfer coil unit 413 is manufactured, the transfer coil unit 413 may be manufactured in consideration of internal resistance and radiation resistance. Here, if the resistance component of the transfer coil unit 413 is low, a quality factor may increase, and transfer efficiency may be improved.

The current detection unit 414 may detect current generated from the transfer coil unit 413. That is, the current detection unit 414 may detect whether the transfer coil unit 413 transfers the wireless power. Also, the current detection unit 414 may transmit information for informing whether the transfer coil unit 413 transfers the wireless power to the control and communication unit 415.

The control and communication unit 415 may be called a microprocessor, a micro controller unit (MCU), or a micom. The control and communication unit 415 may perform communication with the receiver device. For example, the control and communication unit 415 may perform the communication through a short distance communication method such as Bluetooth, NFC, Zigbee, and the like. The control and communication unit 415 and the receiver device may transmit and receive charging status information and a charging control command to and from each other. The charging status information may include the number of wireless power receiver device, a battery remaining amount, the number of times of charging, an amount of usage, a battery capacity, a battery ratio, and a transfer power amount of the transfer device 410. Also, the control and communication unit 415 may transmit a charging function control signal for controlling a charging function of the receiver device. The charging function control signal may be a control signal that controls the wireless power transfer device to enable to disable the charging function.

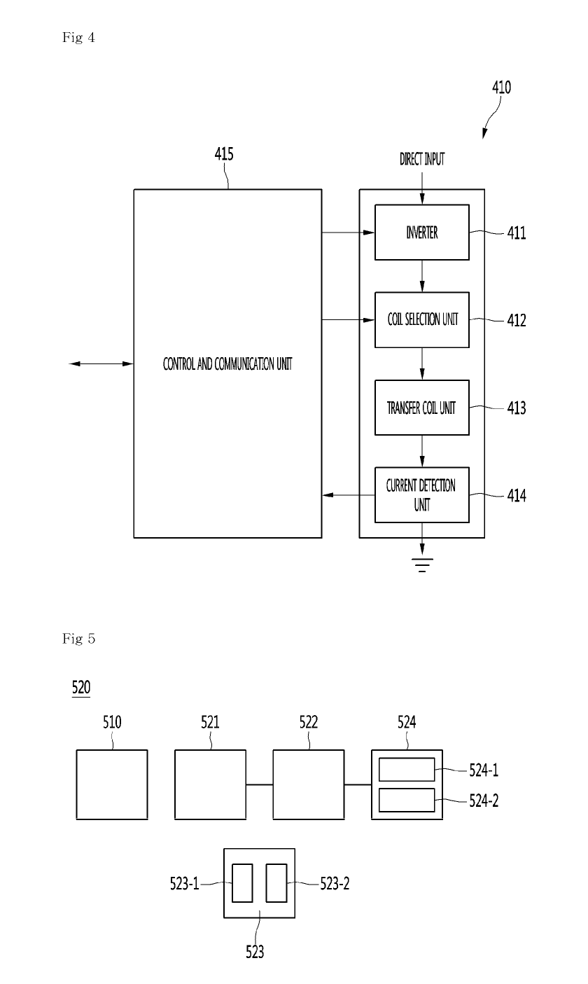

FIG. 5 is a block diagram of the receiver unit as one of the sub system constituting the wireless power transfer system according to an embodiment.

According to an embodiment, the wireless power transfer device 520 may be called a wireless power receiver, a receiver device, or a receiver.

Referring to FIG. 5, the wireless power transfer system according to an embodiment may include a transfer device 510 and a receiver device 520 wirelessly receiving power from the transfer device 510. The receiver device 520 may include a receiver coil unit 521, a power conversion unit 522, and a control and communication unit 524.

The receiver coil unit 521 may receive an AC signal transmitted from the transfer device 510. The power conversion unit 522 may convert the AC power from the receiver coil unit 521 to output a DC signal. The power conversion unit 522 may include a power conversion part that converts an AC signal into DC, a power conversion part that outputs the DC by changing a level of the DC, and a power conversion part that converts DC into AC. According to another embodiment, the power conversion unit 522 may be separately provided from the receiver device 520.

The control and communication unit 523 may sense a current voltage of the receiver coil unit 521. The control and communication unit 523 may control power conversion of the power conversion unit 522. The control and communication unit 523 may adjust a level of the output signal of the power conversion unit 522. The control and communication unit 523 may sense an input or output voltage or current of the power conversion unit 522. The control and communication unit 523 may control whether the output signal of the receiver-side power conversion unit 522 is transmitted to the load 524. The control and communication unit 523 may be divided into a control part 523-1 and a communication part 523-2.

The load 524 may receive the DC signal outputted) from the conversion unit (522 than be charged. The load 524 may include a battery 524-1 and a battery management part 524-2. The battery management part 524-2 may detect a charged state of the battery 524-1 to adjust a voltage and current applied to the battery 524-1.

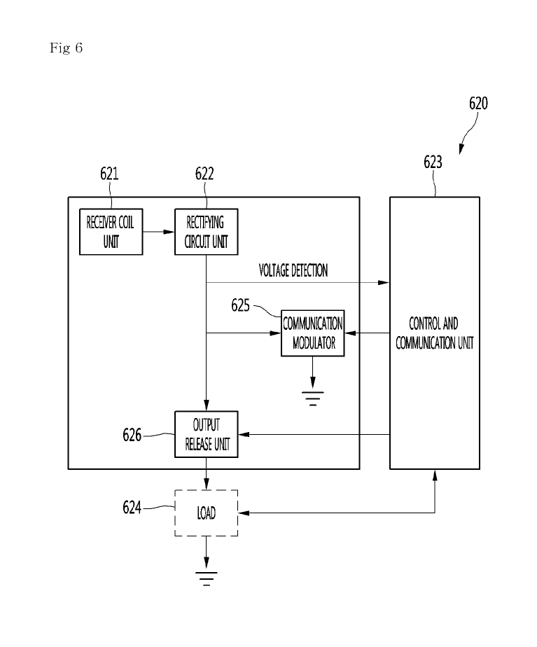

FIG. 6 is a block diagram of a receiver unit device as one of a sub system constituting a wireless power transfer system according to another embodiment.

Referring to FIG. 6, a receiver device 620 according to another embodiment may include a receiver coil unit 621, a power conversion unit 622, a control and communication unit 623, a load 624, a communication modulator 625, and an output release unit 626. The power conversion unit 622 may be called a rectifying circuit part.

The receiver coil unit 621 may be disposed on the receiver device 620 together with a near field communication (NFC) antenna. The receiver coil unit 621 may have the same structure as the transfer coil unit 621. A dimension of the NFC antenna may vary in electrical characteristic of the receiver device 620.

The rectifying circuit unit 622 rectifies the AC signal output from the receiver coil unit 621 to generate a DC signal. An output voltage of the rectifying circuit unit 622 may be called a rectified voltage. The control and communication unit 623 may detect or change the output voltage of the rectifying circuit unit 622. The rectifying circuit unit 622 may adjust a level of the DC signal to match a capacity of the load 624.

The communication modulator 625 may modulate a signal transmitted from the control and communication unit 623. The output release unit 626 may control the power supply to the load 624. For example, the output release unit 626 may turn off a switch provided in the output release unit 626 under the control of the control and communication unit 623 when the power is not supplied to the load 624.

The load 624 may include a battery, a display, a sound output circuit, a main processor, a battery management unit, and various sensors. The load 624 may include a battery and a battery management part.

The control and communication unit 626 may be activated by wake-up power received from the transfer device. The control and communication unit 623 may perform communication with the transfer device. The control and communication unit 623 may control an operation of the sub system of the receiver device 620.

Also, referring to a relationship between the size of a signal and a frequency of the wireless power transfer system, in the case of the wireless power transfer using the magnetic induction method, the power conversion unit of the transfer device may receive an DC signal to output AC current having a frequency of KHz band (for example, 125 KHz). Also, the power conversion unit 622 of the receiver device 620 may receive an AC signal having a frequency of KHz band (for example, 125 KHz) to convert the received AC signal into a DC signal having several voltages to several ten voltages or several hundred voltages, thereby outputting the converted DC signal. For example, the power conversion unit 622 of the receiver device 620 may output a DC signal of 5 V that is adequate for the load 624 to transmit the outputted DC signal to the load 624.

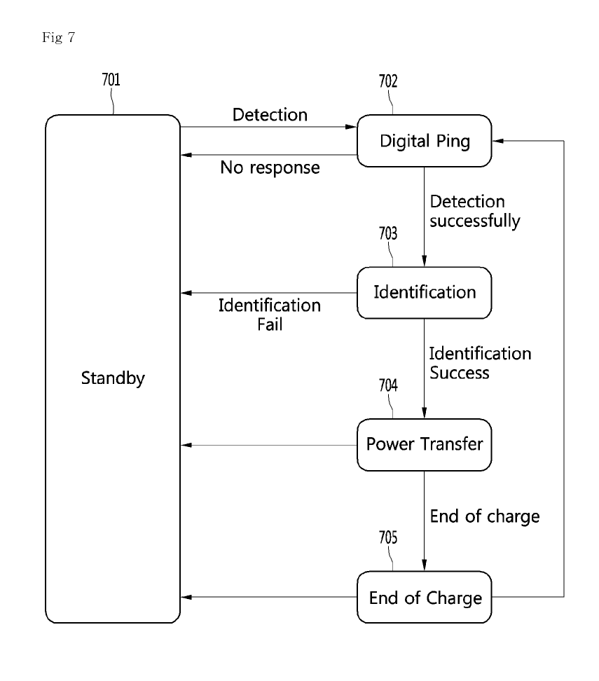

FIG. 7 is a flowchart illustrating an operation of the wireless power transfer system, which is an operation flowchart based on an operation state of the wireless power transfer system according to an embodiment.

Referring to FIG. 7, the transfer unit according to an embodiment may have a standby state 701, a digital ping state 703, an identification state 705, a power transfer state 707, and an end state 709 of charge.

[Standby state 701]

When power is applied to the transfer unit from the outside to drive the transfer unit, the transfer unit may become a standby state. The transfer unit that is in the standby state may detect whether an object disposed on the charging area (for example, the receiver unit or metallic foreign object (FO) exist.

The transfer unit may detect the object by monitoring a variation in magnetic flux, a variation in capacitance or inductance between the object and a transfer unit, or a shift in resonance frequency, but is not limited thereto.

When the transfer unit detects the object that is the receiver unit within the charging area, the standby state may proceed to the digital ping state that is the next process.

[Digital Ping State 702]

In the digital ping state, the transfer unit is connected to a chargeable receiver unit. Also, the transfer unit may confirm whether the receiver unit is in a state of an effective receiver unit that is chargeable with wireless power provided from the transfer unit. Also, the transfer unit may generate and output a digital ping having a predetermined frequency and timing so as to be connected to the chargeable receiver unit.

If a sufficient power signal for the digital ping is transmitted to the receiver unit, the receiver unit may respond to the digital ping by modulating the power signal according to a communication protocol. Also, when the transfer unit receives an effective signal from the receiver unit, the digital ping state may proceed to an identification state without removing the power signal. Also, if request of an end of charge (EOC) is received from the receiver unit, the transfer unit may proceed to the end state of charge.

In addition, when the effective receiver unit is not detected, or when the response time of the object for the digital ping exceeds a preset time, the transfer unit may return to the standby state by removing the power signal.

[Identification State 703]

When the response of the receiver unit according to the digital ping of the transfer unit is completed, the transfer unit may transmit identification information of the transfer unit to the receiver unit to confirm compatibility between the transfer unit and the receiver. Also, when the compatibility is confirmed, the receiver unit may transmit the identification information to the transfer unit. Also, the transfer unit may confirm the identification information of the receiver unit.

When the mutual identification of the transfer unit is completed, the identification state may proceed to a power transfer state. If the identification state fails, or the identification time exceeds a predetermined identification time, the identification state may return to the standby state.

[Power Transfer State 704]

The communication and control unit of the transfer unit may control the transfer unit on the basis of control data received from the receiver unit to provide charging power to the receiver unit.

Furthermore, the transfer unit may verify whether the charging power is out of an appropriate operation range, or stability against the foreign object detection (FOD) is a problem.

Also, when the transfer unit receives the charge end signal from the receiver unit, or the operation range exceeds a predetermined limit temperature value, the transfer unit may stop the power transfer to proceed to the end state of charge.

Also, in the case of a situation where the power is not suitable for the transfer, the transfer unit may remove the power signal and return to the standby state. Also, the transfer unit enters the charging area again after the receiver unit is removed, the above-described cycle may proceed again.

Also, the transfer unit may return to the identification state again according to the charging state of the load of the receiver unit and provide the adjusted charging power to the receiver unit on the basis of the status information of the load.

[End State 705 of Charge]

When the transfer unit receives the information in which the charging is completed from the receiver unit or he receiver unit receives the information in which a temperature is risen above a preset temperature, the power transfer state may proceed to an end state of change.

When the transfer unit receives the charge completion information from the receiver unit, the transfer unit may stop the power transfer and then standby for a predetermined time. Also, the transfer unit may enter the digital ping state so as to be connected to the receiver unit located in the charging area the predetermined time has elapsed.

Also, the transfer unit may standby for the predetermined time when receiving information indicating that the preset temperature is exceeded from the receiver unit. Also, the transfer unit may enter the digital ping state so as to be connected to the receiver unit located in the charging area the predetermined time has elapsed.

Also, the transfer unit may monitor whether the receiver unit is removed from the charge area for a predetermined time. The transfer unit may return to the standby state when the receiver unit is removed from the charging area.

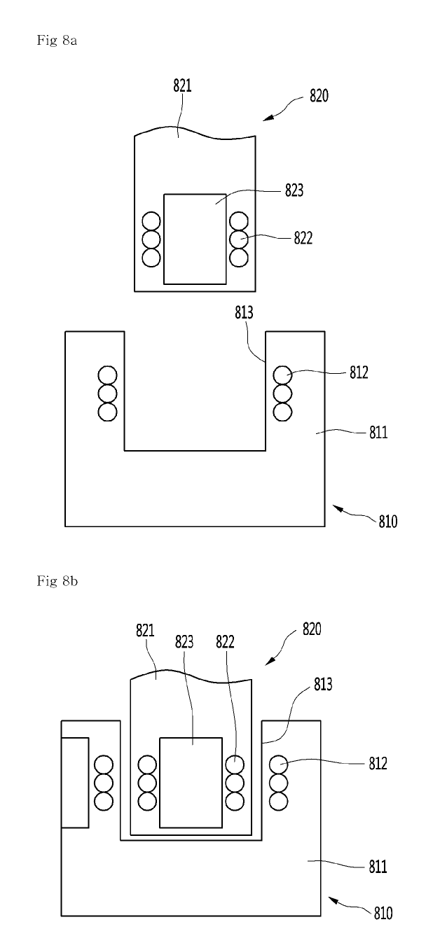

FIGS. 8A to 8C are cross-sectional views of the wireless power transmitter and the wireless power receiver according to an embodiment.

Referring to FIG. 8A, a wireless power receiver 820 may include a receiver coil surrounding a core 823 in the form of a solenoid. The core 823 may have a cylindrical shape or a hexahedral shape. For example, the core 813 may have a shape in which a cylinder, a prism, or a portion of a cylinder has a diameter that gradually increases or decreases. The receiver coil 822 may be disposed to surround the core 823 in a cylindrical or hexahedral structure according to the shape of the core 823. For example, the receiver coil 822 may have a shape in which a cylinder, a prism, or a portion of a cylinder has a diameter that gradually increases or decreases.

The wireless power transmitter 810 may include an accommodation space 813 for accommodating the wireless power receiver 820. The wireless power transmitter 810 may include a transfer coil 821 surrounding the accommodation space 813 in the form of a solenoid. The accommodation space 813 may have a cylindrical shape or a hexahedral shape. For example, the accommodation space 813 may have a shape in which a cylinder, a prism, or a portion of a cylinder has a diameter that gradually increases or decreases. The transfer coil 812 may be disposed to surround the accommodation space 813 in a cylindrical or hexahedral structure according to the shape of the accommodation space 813. For example, the transfer coil 812 may have a shape in which a cylinder, a prism, or a portion of a cylinder has a diameter that gradually increases or decreases.

Referring to FIG. 8B, the wireless power receiver 820 may be inserted into the accommodation space 813. The wireless power receiver 820 may transmit information for identifying the wireless power receiver 820 to the wireless power transmitter 810. The wireless power transmitter 810 may receive information for identifying the wireless power receiver 820 from the wireless power receiver 820. The wireless power transmitter 810 may identify the wireless power receiver 820 on the basis of the information for identifying the wireless power receiver 820.

Referring to FIG. 8C, when the wireless power receiver 820 is identified, the wireless power transmitter 810 may transfer the wireless power to the receiver coil 822 through the transfer coil 812. According to another embodiment, the wireless power transmitter 810 may detect the insertion of the wireless power receiver 820 into the accommodation space 813 without the information for identification. When the wireless power receiver 820 is inserted into the accommodation space 813, the wireless power transmitter 810 may transfer the wireless power to the receiver coil 822 through the transfer coil 812.

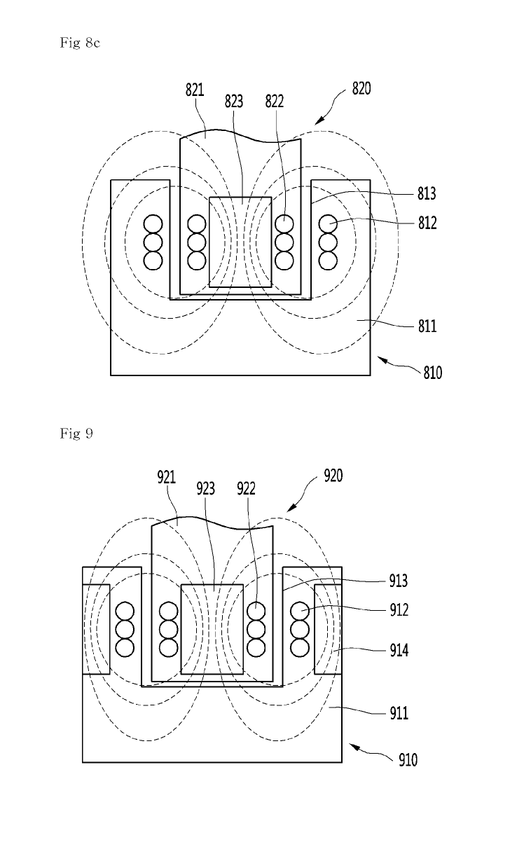

FIG. 9 is a cross-sectional view of a wireless power transmitter and a wireless power receiver according to another embodiment.

Referring to FIG. 9, a wireless power receiver 920 may include a receiver coil 922 surrounding a core 923 in the form of a solenoid. The core 923 may have a cylindrical shape or a hexahedral shape. The receiver coil 922 may be disposed to surround the core 923 in a cylindrical or hexahedral structure according to the shape of the core 923.

The wireless power transmitter 910 may include an accommodation space 913 for accommodating the wireless power receiver 920. The wireless power transmitter 910 may include a transfer coil 921 surrounding the accommodation space 913 in the form of a solenoid. The accommodation space 913 may have a cylindrical shape or a hexahedral shape. The transfer coil 912 may be disposed to surround the accommodation space 913 in a cylindrical or hexahedral structure according to the shape of the accommodation space 913.

The wireless power receiver 920 may be inserted into the accommodation space 913. The wireless power receiver 920 may transmit information for identifying the wireless power receiver 920 to the wireless power transmitter 910. The wireless power transmitter 910 may receive information for identifying the wireless power receiver 920 from the wireless power receiver 920. The wireless power transmitter 910 may identify the wireless power receiver 920 on the basis of the information for identifying the wireless power receiver 920.

When the wireless power receiver 920 is identified, the wireless power transmitter 910 may transfer the wireless power to the receiver coil 922 through the transfer coil 912. According to another embodiment, the wireless power transmitter 910 may detect the insertion of the wireless power receiver 920 into the accommodation space 913 without the information for identification. When the wireless power receiver 920 is inserted into the accommodation space 913, the wireless power transmitter 910 may transfer the wireless power to the receiver coil 922 through the transfer coil 912.

The wireless power transmitter 910 may further include a shield part 914. The shield part 914 may be disposed to surround the transfer coil 912 of the wireless power transmitter 910. The shield part 914 may shield emission of electromagnetic fields, which are generated when the transfer coil 912 transfers the wireless power to the receiver coil 922, to the outside.

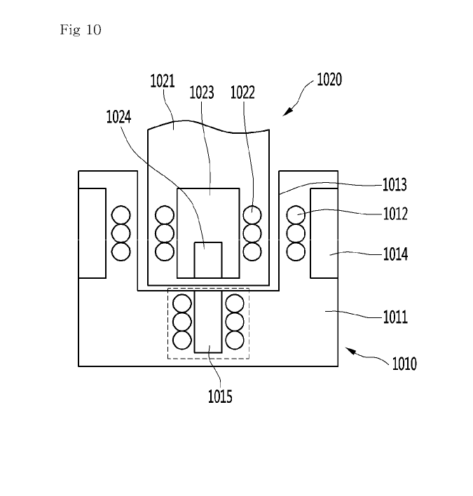

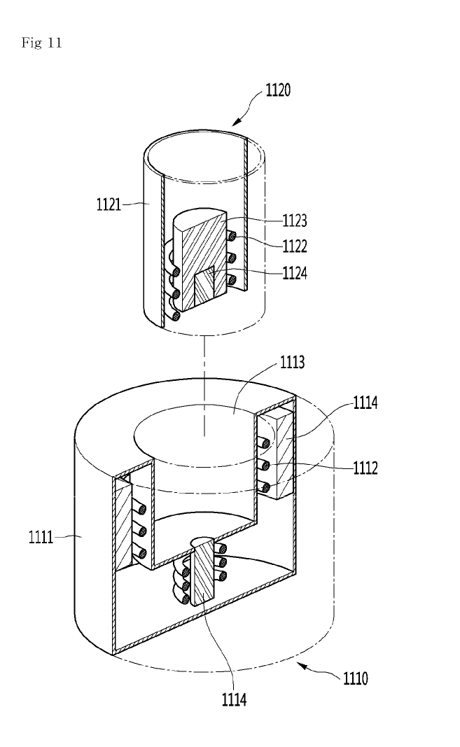

FIG. 10 is a view illustrating structures of a wireless power transmitter and a wireless power receiver according to further another embodiment.

Referring to FIG. 10, a wireless power receiver 1020 may include a receiver coil 1022 surrounding a core 1023 in the form of a solenoid. The core 1023 may have a cylindrical shape or a hexahedral shape. The receiver coil 1022 may be disposed to surround the core 1023 in a cylindrical or hexahedral structure according to the shape of the core 1023.

The wireless power transmitter 1010 may include an accommodation space 1013 for accommodating the wireless power receiver 1020. The wireless power transmitter 1010 may include a transfer coil 1021 surrounding the accommodation space 1013 in the form of a solenoid. The accommodation space 1013 may have a cylindrical shape or a hexahedral shape. The transfer coil 1012 may be disposed to surround the accommodation space 1013 in a cylindrical or hexahedral structure according to the shape of the accommodation space 1013.

The wireless power receiver 1020 may be inserted into the accommodation space 1013. The wireless power receiver 1020 may transmit information for identifying the wireless power receiver 1020 to the wireless power transmitter 1010. The wireless power transmitter 1010 may receive information for identifying the wireless power receiver 1020 from the wireless power receiver 1020. The wireless power transmitter 1010 may identify the wireless power receiver 1020 on the basis of the information for identifying the wireless power receiver 1020.

When the wireless power receiver 1020 is identified, the wireless power transmitter 1010 may transfer the wireless power to the receiver coil 1022 through the transfer coil 1012. According to another embodiment, the wireless power transmitter 1010 may detect the insertion of the wireless power receiver 1020 into the accommodation space 1013 without the information for identification. When the wireless power receiver 1020 is inserted into the accommodation space 1013, the wireless power transmitter 1010 may transfer the wireless power to the receiver coil 1022 through the transfer coil 1012.

The wireless power transmitter 1010 may further include a shield part 1014. The shield part 1014 may be disposed to surround the transfer coil 1012 of the wireless power transmitter 1010. The shield part 1014 may shield emission of electromagnetic fields, which are generated when the transfer coil 1012 transfers the wireless power to the receiver coil 1022, to the outside.

According to an embodiment, the wireless power receiver 1020 may further include a metal body 1024 on a lower end of the core 1023. The metal body 1024 may be a metal or magnet. According to another embodiment, the metal body 1024 may be disposed to be separated from the core 1023.

According to an embodiment, the wireless power receiver 1020 may further include an electromagnet 1015 on a lower end of an accommodation space 1013. The electromagnet 1015 may include pure iron and a coil that surrounds the pure iron in the form of a solenoid. The electromagnet 1015 may be a metal containing iron (Fe). Alternatively, the electromagnet 1015 may be a magnet.

FIG. 11 is a cross-sectional perspective view of a wireless power transmitter and a wireless power receiver according to further another embodiment.

Referring to FIG. 11, a wireless power receiver 1120 may include a receiver coil 1122 surrounding a core 1123 in the form of a solenoid. The core 1123 may have a cylindrical shape or a hexahedral shape. The receiver coil 1122 may be disposed to surround the core 1123 in a cylindrical or hexahedral structure according to the shape of the core 1123.

The wireless power transmitter 1110 may include an accommodation space 1113 for accommodating the wireless power receiver 1120. The wireless power transmitter 1110 may include a transfer coil 1121 surrounding the accommodation space 1113 in the form of a solenoid. The accommodation space 1113 may have a cylindrical shape or a hexahedral shape. The transfer coil 1112 may be disposed to surround the accommodation space 1113 in a cylindrical or hexahedral structure according to the shape of the accommodation space 1113.

The wireless power receiver 1120 may be inserted into the accommodation space 1113. The wireless power receiver 1120 may transmit information for identifying the wireless power receiver 1120 to the wireless power transmitter 1110. The wireless power transmitter 1110 may receive information for identifying the wireless power receiver 1120 from the wireless power receiver 1120. The wireless power transmitter 1110 may identify the wireless power receiver 1120 on the basis of the information for identifying the wireless power receiver 1120.

When the wireless power receiver 1120 is identified, the wireless power transmitter 1110 may transfer the wireless power to the receiver coil 1122 through the transfer coil 1112. According to another embodiment, the wireless power transmitter 1110 may detect the insertion of the wireless power receiver 1120 into the accommodation space 1113 without the information for identification. When the wireless power receiver 1120 is inserted into the accommodation space 1113, the wireless power transmitter 1110 may transfer the wireless power to the receiver coil 1122 through the transfer coil 1112.

The wireless power transmitter 1110 may further include a shield part 1114. The shield part 1114 may be disposed to surround the transfer coil 1112 of the wireless power transmitter 1110. The shield part 1114 may shield emission of electromagnetic fields, which are generated when the transfer coil 1112 transfers the wireless power to the receiver coil 1122, to the outside.

According to an embodiment, the wireless power receiver 1120 may further include a metal body 1124 on a lower end of the core 1123. The metal body 1124 may be a metal or magnet. According to another embodiment, the metal body 1124 may be disposed to be separated from the core 1123.

According to an embodiment, the wireless power receiver 1120 may further include an electromagnet 1115 on a lower end of an accommodation space 1113. The electromagnet 1115 may include pure iron and a coil that surrounds the pure iron in the form of a solenoid. The electromagnet 1115 may be a metal containing iron (Fe). Alternatively, the electromagnet 1115 may be a magnet.

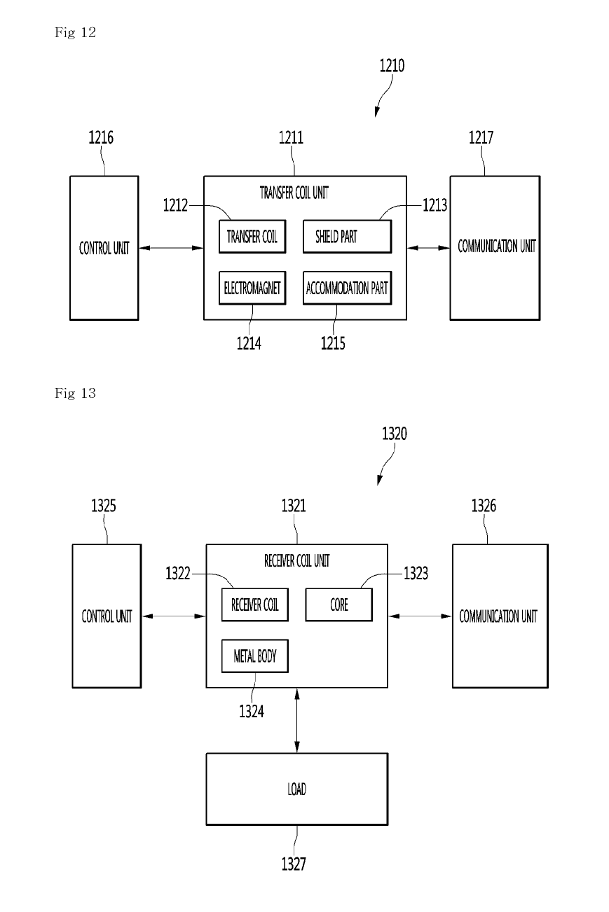

FIG. 12 is a block diagram of the wireless power transmitter according to an embodiment.

Referring to FIG. 12, a wireless power transmitter 1210 according to an embodiment may include a transfer coil unit 1211, a control unit 1216, and a communication unit 1217.

The transfer coil unit 1211 may include a transfer coil 1212, a shield part 1213, an electromagnet 1214, and an accommodation part 1215. The accommodation part 1215 may mean a space for accommodating the wireless power receiver. The transfer coil 1212 may be disposed to surround the accommodation part 1215 in the form of a solenoid. The shield part 1213 may shield magnetic fields generated by the transfer coil 1212. The shield part 1213 may be disposed to surround the transfer coil 1212 in the form of the solenoid. The electromagnet 1214 may generate magnetic force for fixing or separating the wireless power receiver to and from the accommodation part 1215. The electromagnet 1214 may be disposed on a lower end of the accommodation part.

The control unit may determine whether to transfer the wireless power to the wireless power receiver through the transfer coil 1212. When the wireless power is not transferred, the control unit 1216 may control the electromagnet 1214 so that the wireless power receiver is separated from the accommodation part 1215 by release or repulsive force between the electromagnet 1214 and a metal body of the wireless power receiver. When the wireless power is transferred, the control unit 1216 may control the electromagnet 1214 so that the wireless power receiver is fixed due to attractive force between the electromagnet 1214 and the metal body.

When the wireless power is transferred, the control unit 1216 may apply a positive (+) voltage to the electromagnet 1214. The electromagnet 1214 may generate the attractive force with respect to the metal boxy of the wireless power receiver through the applied positive voltage to fix the wireless power receiver to the accommodation part 1215.

When the wireless power is not transferred, the positive voltage may not be applied to the electromagnet 1214, or a negative (−) voltage may be applied to the electromagnet 1214 under the control of the control unit 1216. When the negative voltage is applied, the electromagnet 1214 may generate the repulsive force with respect to the metal boxy of the wireless power receiver through the negative voltage to separate the wireless power receiver from the accommodation part 1215.

The communication unit 1217 may receive information for identifying the wireless power receiver from the wireless power receiver. The communication unit 1217 may receive information on a charging state of the load of the wireless power receiver from the wireless power receiver.

The control unit 1216 may determine whether to transfer the wireless power to the wireless power receiver on the basis of the information on the charging state of the load of the wireless power receiver. The control unit 1216 may determine whether the wireless power receiver is inserted into the accommodation part 1215. According to another embodiment, the control unit 1216 and the communication unit 1217 may be one device.

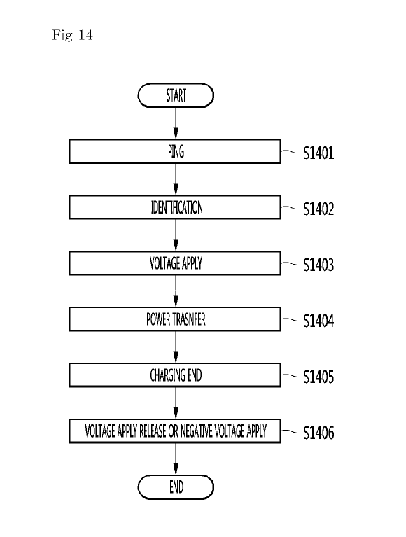

FIG. 13 is a block diagram of the wireless power receiver according to an embodiment.

Referring to FIG. 13, the wireless power transmitter 2700 according to an embodiment may include a receiver coil unit 1321, a control unit 1325, a communication unit 1326, and a load 1327.

The receiver coil unit 1321 may include a core 1323. The receiver coil unit 1321 may include a receiver coil 1322 surrounding a core 1323 in the form of a solenoid. The receiver coil unit 1321 may include a metal body disposed on a lower end of the core 1323. The metal body 1324 may be a metal or magnet. According to another embodiment, the metal body 1324 may be provided in the core 1323.

When the receiver coil 1322 does not receive the wireless power, the metal body 1324 may separate the wireless power receiver 1320 from the wireless power transmitter by using the release of the attractive force or the repulsive force between the metal body 1324 and the electromagnet of the wireless power transmitter. When the receiver coil 1322 receives the wireless power, the metal body 1324 may fix the wireless power receiver 1320 to the wireless power transmitter by using the attractive force between the metal body 1324 and the electromagnet of the wireless power transmitter.

The communication unit 1326 may transmit a signal for identifying the wireless power receiver 1320 to the wireless power transmitter. The load 1327 may store the wireless power received through the receiver coil 1322. The control unit 1325 may determine the charging state of the load 1327. The communication unit 1326 may transmit a signal for informing the charging state of the load 1327 to the wireless power transmitter. The wireless power receiver 1320 may be inserted into the accommodation space 913 of the wireless power transmitter.

FIG. 14 is a flowchart illustrating an operation of the wireless power transmitter according to an embodiment.

Referring to FIG. 14, the wireless power transmitter may receive a ping signal from the wireless power receiver in a standby state (S1401 step). For example, the wireless power transmitter may receive a signal for identifying the wireless power receiver from the wireless power receiver.

The wireless power transmitter may identify the wireless power receiver (S1402 step). For example, the wireless power transmitter may identify the wireless power receiver on the basis of the information for identifying the wireless power receiver. According to an embodiment, the wireless power transmitter may determine whether the wireless power receiver is inserted into the accommodation part of the wireless power transmitter through the identification. According to another embodiment, the wireless power transmitter may determine whether the wireless power receiver is inserted into the accommodation part through the control unit without separate identification.

The wireless power transmitter may apply an AC voltage to an electromagnet of the wireless power transmitter (S1403 step). The wireless power transmitter may apply a DC voltage of the electromagnet after the identifying the wireless power receiver. The wireless power transmitter may control the electromagnet so that attractive force is generated between the electromagnet of the wireless power transmitter and the metal body of the wireless power receiver to fix the wireless power receiver to the accommodation part of the wireless power transmitter. The electromagnet may generate the attractive force between the electromagnet and the metal body of the wireless power receiver by the applied DC voltage. The wireless power receiver may fix the wireless power receiver to the accommodation part of the wireless power transmitter by using the attractive force between the metal body and the electromagnet of the wireless power transmitter.

The wireless power transmitter may transfer and receive the wireless power to and from the wireless power receiver (S1404 step). The wireless power transmitter may transfer the wireless power to the receiver coil of the wireless power receiver through the transfer coil.

The wireless power transmitter may end the wireless power receiver (S1405 step). The wireless power transmitter may receive a signal for informing that the charging is completed with respect to the load of the wireless power receiver from the wireless power receiver. Alternatively, the wireless power transmitter may recognize that the wireless power receiver is out of a range in which the wireless power receiver is capable of receiving the wireless power.

The wireless power transmitter may release the DC voltage applied to the electromagnet (S1406 step). Alternatively, the wireless power transmitter may apply a negative (−) DC voltage to the electromagnet.

The wireless power transmitter may apply a negative DC voltage of the electromagnet so that a repulsive force is generated between the electromagnet of the wireless power transmitter and the metal body of the wireless power receiver. The wireless power transmitter may separate the wireless power receiver from the accommodation part of the wireless power transmitter by using the repulsive force generated between the electromagnet and the metal body.

The wireless power transmitter may release the positive voltage applied to the electromagnet so that the repulsive force between the electromagnet of the wireless power transmitter and the metal body of the wireless power receiver is released. The wireless power transmitter may separate the wireless power receiver from the accommodation part of the wireless power transmitter by releasing the attractive force between the electromagnet and the metal body.

The wireless power transmitter may control the electromagnet so that the repulsive force is generated between the electromagnet of the wireless power transmitter and the metal body of the wireless power receiver to separate the wireless power receiver from the accommodation part of the wireless power transmitter. For example, the wireless power transmitter may apply the positive (+) voltage to the electromagnet to generate the attractive force between the electromagnet and the metal body of the wireless power receiver. The wireless power receiver may be fixed to the accommodation part of the wireless power transmitter by the generated attractive force.

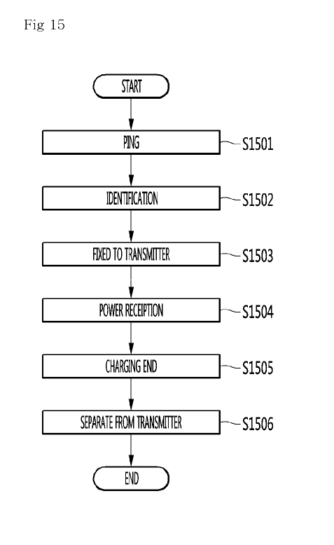

FIG. 15 is a flowchart illustrating an operation of the wireless power receiver according to an embodiment.

Referring to FIG. 15, the wireless power receiver may transmit a ping signal to the wireless power transmitter (S1501 step). The ping signal may be a signal for identifying the wireless power receiver. For example, the wireless power receiver may transmit information for identifying the wireless power receiver to the wireless power transmitter.

The wireless power receiver may be identified to the wireless power transmitter (S1502 step). For example, the wireless power receiver may be identified from the wireless power transmitter on the basis of the information for identifying the wireless power receiver.

The wireless power receiver may be fixed to the wireless power transmitter (S1503 step). The wireless power receiver may be fixed to the wireless power transmitter by the attractive force between the electromagnet of the wireless power transmitter and the metal body of the wireless power receiver is released.

The wireless power receiver may receive the wireless power from the wireless power transmitter (S1504 step). The wireless power receiver may receive the wireless power from the transfer coil of the wireless power transmitter through the receiver coil of the wireless power receiver.

The wireless power receiver may end the charging (S1505 step). The wireless power receiver may transmit information for informing that the charging is completed with respect to the load of the wireless power receiver to the wireless power transmitter.

The wireless power receiver may be separated from the wireless power transmitter. The wireless power receiver may be separated from the wireless power transmitter due to the release of the attractive force or the repulsive force between the electromagnet of the wireless power transmitter and the metal body of the wireless power receiver.

### INDUSTRIAL APPLICABILITY

Embodiments may be used in the wireless power transfer and receiver industries.

1. A wireless power transmitter comprising:
an accommodation part configured to accommodate a wireless power receiver;
a transfer coil configured to surround the accommodation part in the form of a solenoid;
a shield unit configured to surround the transfer coil in the form of the solenoid;
an electromagnet disposed on a lower end of the accommodation part to fix the wireless power receiver; and
a control unit configured to determine whether to transfer the wireless power to the wireless power receiver through the transfer coil,
wherein the control unit controls the electromagnet so that the wireless power receiver is separated from the accommodation part due to a release of attractive force or repulsive force between the electromagnet and a metal body of the wireless power receiver when the wireless power is not transferred.

2. The wireless power transmitter of claim 1, wherein the control unit controls the electromagnet so that the attractive force is generated between the electromagnet and the metal body to fix the wireless power receiver to the accommodation part.

3. The wireless power transmitter of claim 2, wherein the control unit applies a positive (+) voltage to the electromagnet to generate the attractive force between the electromagnet and the metal body when the wireless power is transferred, and the electromagnet generates the attractive force with respect to the metal body through the applied positive voltage to fix the wireless power receiver to the accommodation part.

4. The wireless power transmitter of claim 1, wherein the control unit releases the positive voltage applied to the electromagnet to separate the wireless power receiver from the accommodation part due to the release of the positive voltage when the wireless power is not transferred.

5. The wireless power transmitter of claim 1, wherein the control unit applies a negative (−) voltage to the electromagnet to generate repulsive force between the electromagnet and the magnetic body through the negative voltage, thereby separating the wireless power receiver from the accommodation part.

6. The wireless power transmitter of claim 1, wherein the communication unit receives information on a charging state of a load of the wireless power receiver from the wireless power receiver, and
the control unit determines whether to transfer the wireless power on the basis of the information with respect to the charging state of the load.

7. The wireless power transmitter of claim 1, wherein the control unit determines whether the wireless power receiver is inserted into the accommodation part.

8. A wireless power receiver comprising:
a receiver coil configured to surround a core in the form of a solenoid; and
a metal body disposed on a lower end of the core,
wherein, when the receiver coil does not receive the wireless power, the wireless power receiver is separated from the wireless power transmitter due to a release of attractive force or repulsive force between an electromagnet of the wireless power transmitter and a magnetic body.

9. The wireless power receiver of claim 8, wherein the magnetic body fixes the wireless power receiver to the wireless power receiver due to attractive force between the electromagnet and the metal body when the wireless power is received into the receiver coil.

10. The wireless power receiver of claim 8, further comprising:
a communication unit configured to transmit a signal for identifying the wireless power receiver to the wireless power transmitter;
a load configured to store the wireless power received through the receiver coil; and
a control unit configured to determine a charging state of the load.

11. The wireless power receiver of claim 10, wherein the communication unit transmits a signal for informing the charging state of the load to the wireless power transmitter.

12. The wireless power receiver of claim 8, wherein the wireless power receiver is inserted into an accommodation part of the wireless power transmitter.

13. A method for operating a wireless power transmitter, the method comprising:
being in standby state;
transmitting and receiving a ping signal to and from a wireless power receiver;
identifying the wireless power receiver;
transferring wireless power to the wireless power receiver; and
ending the wireless power transfer,
wherein the identifying of the wireless power receiver comprises recognizing that the wireless power receiver is inserted into an accommodation part of the wireless power transfer unit, and
the ending of the wireless power transfer comprises controlling the electromagnet so that the wireless power receiver is separated from the accommodation part due to a release of attractive force or repulsive force between an electromagnet and a metal body of the wireless power receiver.

14. The method of claim 13, wherein the transferring of the wireless power comprises controlling the electromagnet so that the attractive force is generated between the electromagnet and the metal body to fix the wireless power receiver to the accommodation part.

15. The method of claim 14, wherein the transferring of the wireless power comprises controlling the electromagnet so that a positive (+) voltage is applied to the electromagnet to generate the attractive force between the electromagnet and the metal body, thereby fixing the wireless power receiver to the accommodation part.

16. The method of claim 13, wherein the ending of the wireless power transfer comprises releasing a positive voltage applied to the electromagnet, and
the releasing of the positive voltage applied to the electromagnet comprises controlling the electromagnet so that the applied positive voltage is released to separate the wireless power receiver from the accommodation part.

17. The method of claim 13, wherein the ending of the wireless power transfer comprises applying a negative (−) voltage applied to the electromagnet, and
the applying of the negative voltage to the electromagnet comprises controlling the electromagnet so that the negative voltage is applied to generate repulsive force between the electromagnet and the metal body, thereby separating the wireless power receiver from the accommodation part.

18. A method for operating a wireless power receiver, the method comprising:
transmitting information for identifying the wireless power receiver to a wireless power transmitter;
fixing the wireless power receiver to the wireless power transmitter by attractive force between an electromagnet of the wireless power transmitter and a metal body of the wireless power receiver;
receiving wireless power from the wireless power transmitter:
transmitting information for informing that charging is completed with respect to a battery of the wireless power receiver to the wireless power transmitter; and
separating the wireless power transmitter from the wireless power receiver due to release of the attractive force or the repulsive force between the electromagnet of the wireless power transmitter and the metal body of the wireless power receiver.

19. The method of claim 18, wherein the magnetic body fixes the wireless power receiver to the wireless power receiver due to the attractive force between the electromagnet and the metal body when the wireless power is received into the receiver coil.

20. The method of claim 18, further comprising:
transmitting a signal for identifying the wireless power receiver to the wireless power transmitter;
storing the wireless power received through the receiver coil; and
determining a charging state of the load.

21. (canceled)

22. (canceled)
